(19) United States
(12) Patent Application Publication
(10) Pub. No.: US 2025/0194112 A1
(43) Pub. Date: Jun. 12, 2025

(54) METHODS OF FORMING MICROELECTRONIC DEVICES, AND RELATED MICROELECTRONIC DEVICES AND MEMORY DEVICES

(71) Applicant: Micron Technology, Inc., Boise, ID (US)

(72) Inventors: Fatma Arzum Simsek-Ege, Boise, ID (US); Huicheng Chang, Meridian, ID (US)

(21) Appl. No.: 18/941,708

(22) Filed: Nov. 8, 2024

Related U.S. Application Data
(60) Provisional application No. 63/607,707, filed on Dec. 8, 2023.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436

(57) ABSTRACT

A microelectronic device includes a memory array structure and a control circuitry structure vertically overlying and attached to the memory array structure. The memory array structure includes an array region having memory cells within a horizontal area thereof. The control circuitry structure includes a control circuitry region and a power rail structure. The control circuitry region horizontally overlaps the array region of the memory array structure and has control logic devices within a horizontal area thereof. At least some of the control logic devices are coupled to the memory cells of the memory array structure. The power rail structure is outside of the horizontal area of the control circuitry region. Related methods, memory devices, and electronic systems are also described.

### CROSS-REFERENCE TO RELATED APPLICATION

This application claims the benefit under 35 U.S.C. § 119 (e) of U.S. Provisional Patent Application Ser. No. 63/607,707, filed Dec. 8, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices and memory devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random access memory (DRAM) device. A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device,

### BRIEF DESCRIPTION OF THE DRAWINGS

FIG. 1A is a simplified, partial plan view of a memory array structure at a processing stage of a method of forming a microelectronic device, in accordance with embodiments of the disclosure. FIG. 1B is a diagram showing different simplified, vertical cross sectional views of the memory array structure shown in FIG. 1A, taken about lines A-A and B-B of FIG. 1A.

FIG. 2A is a simplified partial plan view of a control circuitry structure at a processing stage of the method of forming a microelectronic device, in accordance with embodiments of the disclosure. FIG. 2B is a diagram showing different simplified, vertical cross sectional views of the memory array structure shown in FIG. 2A, taken about lines A′-A′ and B′-B′ of FIG. 2A.

FIG. 3 is a diagram showing different simplified, vertical cross sectional views of an assembly formed from the memory array structure of FIGS. 1A and 1B and the control circuitry structure of FIGS. 2A and 2B at a processing stage of the method of forming a microelectronic device following the processing stage of FIGS. 1A and 1B and the processing stage of FIGS. 2A and 2B, in accordance with embodiments of the disclosure.

FIG. 4 is a diagram showing different simplified, vertical cross sectional views at a processing stage of the method of forming a microelectronic device following the processing stage of FIG. 3, in accordance with embodiments of the disclosure.

FIG. 5 is a diagram showing different simplified, vertical cross sectional views at a processing stage of the method of forming a microelectronic device following the processing stage of FIG. 4, in accordance with embodiments of the disclosure.

FIG. 6 is a diagram showing different simplified, vertical cross sectional views at a processing stage of the method of forming a microelectronic device following the processing stage of FIG. 5, in accordance with embodiments of the disclosure.

FIG. 7 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 104 S/cm (106 S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

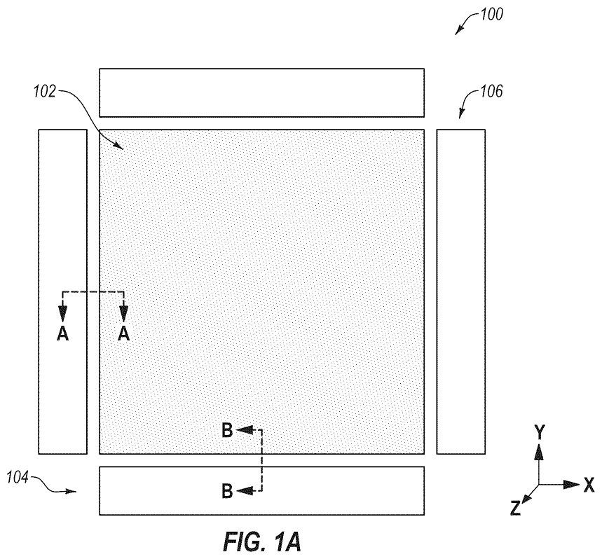

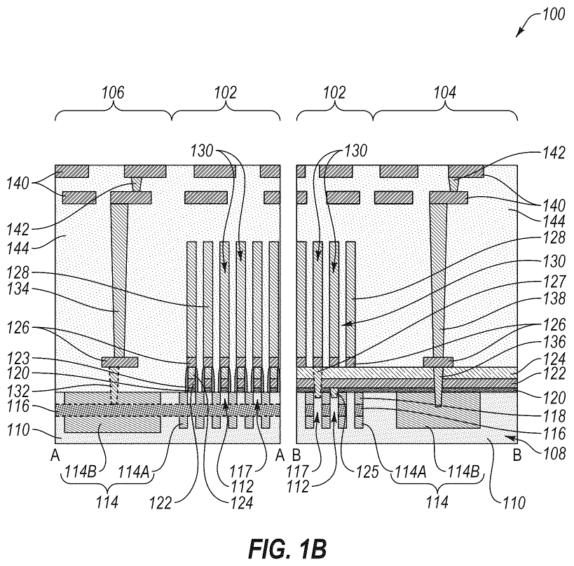

FIGS. 1A through 6 are various views (described in further detail below) illustrating different processing stages of a method of forming a microelectronic device (e.g., a memory device, such as a DRAM device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device. With the description provided below, it will be readily apparent to one of ordinary skill in the art that the methods and structures described herein may be used to form various devices and electronic systems.

FIG. 1A shows a simplified, partial plan view of a memory array structure 100 (e.g., a first wafer, a first die) at an early processing stage of a method of forming a microelectronic device (e.g., a memory device, such as a DRAM device), in accordance with embodiments of the disclosure. As shown in FIG. 1A, the memory array structure 100 may be formed to include an array region 102, digit line exit regions 104 (also referred to as “digit line contact socket regions”) horizontally neighboring the array region 102 in a Y-direction (e.g., a first horizontal direction), and word line exit regions 106 (also referred to as “word line contact socket regions”) horizontally neighboring the array region 102 in an X-direction (e.g., a second horizontal direction) orthogonal to the Y-direction. The array region 102, the digit line exit regions 104, and the word line exit regions 106 are each described in further detail below. FIG. 1B is a diagram showing different simplified, vertical cross sectional views of the memory array structure 100 shown in FIG. 1A, taken about lines A-A and B-B of FIG. 1A. The vertical cross section of the memory array structure 100 taken about line A-A is a view of an XZ-plane of a portion of the memory array structure 100 horizontally overlapping the array region 102 and one of the digit line exit regions 104 of the memory array structure 100. The vertical cross section of the memory array structure 100 taken about line B-B is a view of a YZ-plane of an additional portion of the memory array structure 100 overlapping the array region 102 and one of the word line exit regions 106 of the memory array structure 100.

Referring to FIG. 1A, the array region 102 of the memory array structure 100 is a horizontal area of the memory array structure 100 configured to have an array of memory cells (e.g., an array of DRAM cells) therein, as described in further detail below. The memory array structure 100 may include a desired quantity and distribution of array regions 102. For clarity and ease of understanding of the drawings and related description, FIG. 1A depicts the memory array structure 100 as including one (1) array region 102, but the memory array structure 100 may be formed to include multiple (e.g., more than one (1)) array regions 102 horizontally offset (e.g., in one or more of the X-direction and the Y-direction) from one another. For example, the memory array structure 100 may include greater than or equal to four (4) array regions 102, greater than or equal to eight (8) array regions 102, greater than or equal to sixteen (16) array regions 102, greater than or equal to thirty-two (32) array regions 102, greater than or equal to sixty-four (64) array regions 102, greater than or equal to one hundred twenty eight (128) array regions 102, greater than or equal to two hundred fifty six (256) array regions 102, greater than or equal to five hundred twelve (512) array regions 102, or greater than or equal to one thousand twenty-four (1024) array regions 102.

The digit line exit regions 104 of the memory array structure 100 include horizontal areas of the memory array structure 100 configured include portions of digit line structures (e.g., bit line structures, data line structures) within horizontal boundaries thereof. For an individual digit line exit region 104, at least some digit line structures operatively associated with the array region 102 horizontally neighboring the digit line exit region 104 in the Y-direction may have portions within the horizontal area of the digit line exit region 104. In addition, the digit line exit regions 104 may also be configured to include conductive contact structures and conductive routing structures within the horizontal areas thereof that are operatively associated with the digit line structures. As described in further detail below, some of the conductive contact structures within the digit line exit regions 104 may couple the digit line structures to control logic circuitry of control logic devices (e.g., sense amplifier (SA) devices) to subsequently be provided vertically over the memory array structure 100. As shown in FIG. 1A, in some embodiments, the digit line exit regions 104 respectively horizontally extend in the X-direction. An individual array region 102 may be horizontally interposed between horizontally neighboring digit line exit regions 104 in the Y-direction.

The word line exit regions 106 of the memory array structure 100 include additional horizontal areas of the memory array structure 100 configured include portions of word line structures (e.g., access line structures) within horizontal boundaries thereof. For an individual word line exit region 106, at least some word line structures operatively associated with the array region 102 horizontally neighboring the word line exit region 106 in the X-direction may have portions within the horizontal area of the word line exit region 106. In addition, the word line exit regions 106 may also be configured to include additional conductive contact structures and additional conductive routing structures within the horizontal areas thereof that are operatively associated with the word line structures. As described in further detail below, some of the additional conductive contact structures within the word line exit regions 106 may couple the word line structures to additional control logic circuitry of additional control logic devices (e.g., sub word line driver (SWD) devices) to subsequently be provided vertically over the memory array structure 100. As shown in FIG. 1A, in some embodiments, the word line exit regions 106 respectively horizontally extend in the Y-direction. An individual array region 102 may be horizontally interposed between horizontally neighboring word line exit regions 106 in the X-direction.

Referring next to FIG. 1B, the memory array structure 100 may be formed to include a first base structure 108 including semiconductor material 110 and isolation structures 114 (e.g., shallow trench isolation (STI) structures) vertically extending into the semiconductor material 110. The isolation structures 114 may define boundaries of active regions 112 of the semiconductor material 110, as described in further detail below.

The first base structure 108 comprises a base material or construction upon which additional features (e.g., materials, structures, devices) of the memory array structure 100 are formed. The first base structure 108 may comprise a semiconductor structure (e.g., a semiconductor wafer), or a base semiconductor material on a supporting structure. For example, the first base structure 108 may comprise a conventional silicon substrate (e.g., a conventional silicon wafer), or another bulk substrate comprising a semiconductor material. In some embodiments, the first base structure 108 comprises a silicon wafer. The first base structure 108 may include one or more layers, structures, and/or regions formed therein and/or thereon.

The isolation structures 114 of the memory array structure 100 may comprise trenches (e.g., openings, vias, apertures) within the semiconductor material 110 of first base structure 108 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the isolation structures 114 are respectively formed of and include SiOₓ (e.g., SiO₂).

The isolation structures 114 may include first isolation structures 114A and second isolation structures 114B. The first isolation structures 114A may have one or more different geometric configuration(s) (e.g., different dimension(s), different shape(s)) and different horizontal positioning relative to the second isolation structures 114B. As shown in FIG. 1B, in some embodiments, the first isolation structures 114A are respectively positioned within a horizontal area of the array region 102 of the memory array structure 100; and the second isolation structures 114B are respectively positioned within a horizontal area of one of the digit line exit regions 104 one of the word line exit regions 106 of the memory array structure 100. In addition, at least some of the first isolation structures 114A may respectively have different horizontal dimension(s) than at least some of the second isolation structures 114B. At least some of the isolation structures 114 (e.g., at least some of the first isolation structures 114A and/or at least some of the second isolation structures 114B) vertically extend to and terminate at a different vertical position than some other of the isolation structures 114 (e.g., at least some other of the first isolation structures 114A and/or at least some other of the second isolation structures 114B). For example, some of the isolation structures 114 may be formed to be relatively vertically shallower than some other of the isolation structures 114. Some of the isolation structures 114 may be employed as shallow trench isolation (STI) structures within the first base structure 108.

Within the array region 102 of the memory array structure 100, some of the isolation structures 114 (e.g., some of the first isolation structures 114A) may at least partially define boundaries of the active regions 112 of the semiconductor material 110 of the first base structure 108. The active regions 112 of the semiconductor material 110 may individually vertically extend (e.g., project) from a relatively lower portion of the semiconductor material 110 that horizontally extends across and between the active regions 112. The active regions 112 may be considered pillar structures of the semiconductor material 110.

The active regions 112 of the semiconductor material 110 may individually exhibit an elongate (e.g., non-circular, non-square) horizontal cross-sectional shape at least partially defined by the horizontal cross-sectional shapes of the first isolation structures 114A horizontally adjacent thereto. The active regions 112 may individually include an upper surface, opposing horizontal ends, and opposing horizontal sides extending form and between the opposing ends. Intersections of the opposing horizontal ends of an individual active region 112 with the opposing horizontal sides of the active region 112 may define horizontal corners of the active region 112. As shown in FIG. 1B, the upper surfaces of the active regions 112 may be substantially coplanar with one another. In addition, an individual active region 112 may include a digit line contact region (e.g., bit line contact region) and storage node contact regions (e.g., cell contact regions). The storage node contact regions of the active region 112 may be located proximate the opposing horizontal ends of the active region 112, and the digit line contact region may be horizontally interposed between the storage node contact regions. The digit line contact region may be positioned at or proximate a horizontal center of the active region 112. In some embodiments, the digit line contact region of an individual active region 112 is horizontally narrower (e.g., in the X-direction shown in FIG. 1A) than each of the storage node contact regions of the active region 112. The digit line contact region and the storage node contact regions of an individually active region 112 may be separated from one another by a pair of the first isolation structures 114A.

With continued reference to FIG. 1B, word line structures 116 may be at least partially embedded within the isolation structures 114 and may horizontally extend in parallel in the X-direction (FIG. 1A) completely through the array region 102 and at least partially through the word line exit region 106. At least some of the word line structures 116 may terminate within the word line exit region 106. In the portion of FIG. 1B showing a vertical cross section of the memory array structure 100 about line A-A, the illustrated word line structure 116 is depicted by way of dashed lines to represent that it is outside of (e.g., horizontally offset in the Y-direction (FIG. 1A) from) the vertical plane (e.g., XZ-plane) of line A-A. As shown in FIG. 1B, tops (e.g., upper vertical boundaries) of the word line structures 116 may be substantially coplanar with one another. Side surfaces and a bottom surface of an individual word line structure 116 may be covered by insulative material of a respective one of the isolation structures 114. For example, portions of the isolation structure 114 may be horizontally interposed between the word line structure 116 and a respective active region 112 of the semiconductor material 110 of the first base structure 108. The word line structures 116 may individually be formed of and include conductive material. In some embodiments, the word line structures 116 are individually formed of and include one or more of W, Ru, Mo, and TiN_{y}.

Within the array region 102, the memory array structure 100 further includes access devices 117. The access devices 117 may individually include a channel region comprising a portion of an active region 112 of the semiconductor material 110 of the first base structure 108; a source region and a drain region respectively horizontally neighboring the channel region and individually comprising a conductively doped portion of the active region 112 of the semiconductor material 110 of the first base structure 108; at least one gate structure comprising a portion of at least one of the word line structures 116; and a gate dielectric structure comprising a portion of the insulative material of the first isolation structure 114A interposed between the channel region thereof and the gate structure thereof.

Still referring to FIG. 1B, word line capping structures 118 may be formed on or over the word line structures 116. The word line capping structures 118 may at least partially (e.g., substantially) cover upper surfaces of the word line structures 116, and may horizontally neighbor the active regions 112 of the semiconductor material 110 of the first base structure 108. The word line capping structures 118 may individually be formed of and include at least one insulative material. In some embodiments, the word line capping structures 118 are individually formed of and include dielectric nitride material (e.g., SiN_{y}, such as Si₃N₄).

The memory array structure 100 may further include a first dielectric material 120 on or over the first base structure 108. Within the array region 102, the first dielectric material 120 may overlie the access devices 117. The first dielectric material 120 may individually be formed of and include insulative material. In some embodiments, the first dielectric material 120 is formed of and includes dielectric oxide material (e.g., SiOₓ, such as SiO₂).

With continued reference to FIG. 1B, digit line structures 122 may vertically overlie the first dielectric material 120, and may horizontally extend in parallel in the Y-direction (FIG. 1A) completely through the array region 102 and at least partially through the digit line exit region 104. At least some of the digit line structures 122 may terminate within the digit line exit region 104. As shown in FIG. 1B, tops (e.g., upper vertically boundaries) of the digit line structures 122 may be substantially coplanar with one another. The digit line structures 122 may individually be formed of and include conductive material. In some embodiments, the digit line structures 122 are individually formed of and include one or more of W, Ru, Mo, and TiN_{y}.

Still referring to FIG. 1B, digit line capping structures 124 may be formed on or over upper surfaces of the digit line structures 122, and digit line spacer structures 123 may be formed on or over side surfaces (e.g., sidewalls) of the digit line structures 122. The digit line capping structures 124 may at least partially (e.g., substantially) cover the upper surfaces of the digit line structures 122, the digit line spacer structures 123 may at least partially (e.g., substantially) cover the upper surfaces of the digit line structures 122. As shown in FIG. 1B, in some embodiments, upper boundaries of the digit line spacer structures 123 vertically overlie the upper surfaces of the digit line structures 122, and lower boundaries of the digit line spacer structures 123 vertically underlie lower surfaces of the digit line structures 122. The digit line capping structures 124 and the digit line spacer structures 123 may individually be formed of and include at least one insulative material. In some embodiments, the digit line capping structures 124 and the digit line spacer structures 123 are individually formed of and include one or more of dielectric oxide material (e.g., SiOₓ, such as SiO₂) and dielectric nitride material (e.g., SiN_{y}, such as Si₃N₄).

Within the array region 102, the memory array structure 100 may further include digit line contact structures 125 (also referred to herein as “DIGITCON” structures) vertically overlying and in contact with the active regions 112 of the semiconductor material 110 of the first base structure 108. The digit line contact structures 125 may vertically extend through the first dielectric material 120 and into the active regions 112 of the semiconductor material 110 of the first base structure 108. The digit line contact structures 125 horizontally overlap (e.g., in the X-direction and the Y-direction shown in FIG. 1A) digit line contact sections of the active regions 112. The digit line contact structures 125 may respectively vertically extend from a digit line contact section of an individual active region 112, through the first dielectric material 120, and to an individual digit line structure 122. An individual digit line contact structure 125 may be horizontally interposed between two (2) of the word line structures 116 (and, hence, two (2) of the isolation structures 114) neighboring one another in the Y-direction (FIG. 1A), and may be horizontally interposed between two (2) of storage node contact sections of an individual active region 112 in an additional horizontal direction angled relative to the Y-direction (FIG. 1A) and the X-direction (FIG. 1A). An individual digit line contact structure 125 may be coupled to one of the source/drain regions (e.g., the source region) of an individual access device 117 of the memory array structure 100. Within the horizontal area of an individual active region 112, an individual digit line contact structure 125 may be coupled to two (2) (e.g., a pair) of the access devices 117 operatively associated with the active region 112. For example, the two (2) of the access devices 117 may share a source region within the active region 112 with one another, and the digit line contact structure 125 may be coupled to the shared source region of the two (2) of the access devices 117. The digit line contact structures 125 may individually be formed of and include conductive material.

Within the array region 102, the memory array structure 100 may further include storage node contact structures 127 (also referred to herein as “CELLCON” structures) vertically overlying and in contact with the active regions 112 of the semiconductor material 110 of the first base structure 108. The storage node contact structures 127 may vertically extend through the first dielectric material 120 and into the active regions 112 of the semiconductor material 110 of the first base structure 108. The storage node contact structures 127 horizontally overlap (e.g., in the X-direction and the Y-direction shown in FIG. 1A) storage node contact sections of the active regions 112. In the portion of FIG. 1B showing a vertical cross section of the memory array structure 100 about line B-B, the illustrated storage node contact structure 127 is depicted by way of dashed lines to represent that it is outside of (e.g., horizontally offset in the X-direction (FIG. 1A) from) the vertical plane (e.g., YZ-plane) of line B-B. The storage node contact structures 127 may respectively vertically extend from a storage node contact section of an individual active region 112, through the first dielectric material 120, and to a redistribution material (RDM) structure 126 vertically overlying the digit line capping structures 124. An individual storage node contact structure 127 may be horizontally interposed between two (2) of the word line structures 116 (and, hence, two (2) of the isolation structures 114) neighboring one another in the Y-direction (FIG. 1A), and may horizontally neighbor the digit line contact section of an individual active region 112 in an additional horizontal direction angled relative to the Y-direction (FIG. 1A) and the X-direction (FIG. 1A). An individual storage node contact structure 127 may be coupled to one of the source/drain regions (e.g., the drain region) of an individual access device 117 of the memory array structure 100. Within the horizontal area of an individual active region 112, an individual storage node contact structure 127 may be coupled to one (1) of two (2) (e.g., a pair) of access devices 117 operatively associated with the active region 112. For example, the two (2) of the access devices 117 have separate drain regions than one another within the active region 112, and the individual storage node contact structure 127 may be coupled to the drain region of one (1) of the two (2) of the access devices 117. An individual active region 112 of the semiconductor material 110 may have two (2) storage node contact structures 127 in contact therewith. The storage node contact structures 127 may individually be formed of and include conductive material.

Still referring to FIG. 1B, a redistribution material (RDM) tier (also referred to as “redistribution layer” (RDL) tier) may be formed to vertically overlie the digit line capping structures 124 and may include RDM structures 126 (also referred to as RDL structures). Within the array region 102, at least some of the RDM structures 126 may, for example, be employed to facilitate a horizontal arrangement (e.g., a hexagonal close packed arrangement) of storage node devices 128 that is different than a horizontal arrangement of the storage node contact structures 127, while electrically connecting the storage node contact structures 127 (and, hence, the access devices 117) to the storage node devices 128. In addition, within the digit line exit region 104 and the word line exit region 106, at least some other of the RDM structures 126 may vertically extend between and couple vertically neighboring conductive contact structures with the digit line exit region 104 and the word line exit region 106, as described in further detail below. The RDM structures 126 may individually be formed of and include conductive material. In some embodiments, the RDM structures 126 are individually formed of and include one or more of W, Ru, Mo, and TiN_{y}.

Within the array region 102, the storage node devices 128 (e.g., capacitors) may be formed on or over the RDM structures 126. The storage node devices 128 may be in electrical contact with the RDM structures 126, and, hence with the storage node contact structures 127, and the access devices 117. The storage node devices 128 may be coupled to the access devices 117 by way of the storage node contact structures 127 and the RDM structures 126 to form memory cells 130 (e.g., DRAM cells) within the array region 102. Each memory cell 130 may individually include one of the access devices 117, one of the storage node devices 128, one of the storage node contact structures 127, and one of the RDM structures 126. The storage node devices 128 may individually be formed and configured to store a charge representative of a programmable logic state of the memory cell 130 including the storage node device 128. In some embodiments, the storage node devices 128 are capacitors. During use and operation, a charged capacitor may represent a first logic state, such as a logic 1; and an uncharged capacitor may represent a second logic state, such as a logic 0. Each of the storage node devices 128 may, for example, be formed to include a first electrode (e.g., a bottom electrode), a second electrode (e.g., a top electrode), and a dielectric material between the first electrode and the second electrode.

Within the word line exit regions 106, the memory array structure 100 further includes first word line contact structures 132 and second word line contact structures 134. Within an individual word line exit region 106, the first word line contact structures 132 may vertically extend between and couple some of the RDM structures 126 and some of the word line structures 116; and the second word line contact structures 134 may vertically extend between and couple some of the RDM structures 126 and some of first routing structures 140 vertically overlying the memory cells 130. The first world line contact structures 132 and second word line contact structures 134 may be considered to be so-called “edge of array” word line contact structures. In the portion of FIG. 1B showing a vertical cross section of the memory array structure 100 about line A-A, the illustrated first word line contact structure 132 is depicted by way of dashed lines to represent that it is outside of (e.g., horizontally offset in the Y-direction (FIG. 1A) from) the vertical plane (e.g., XZ-plane) of line A-A. An individual first word line contact structure 132 may be formed to have an upper surface in physical contact with one of the RDM structures 126; and a lower surface on, within, or below one of the word line structures 116. In addition, an individual second word line contact structure 134 may be formed to have an upper surface in physical contact with one of the conductive routing structures 14; and a lower surface on, within, or below one of the RDM structures 126. The first word line contact structures 132 and the second word line contact structures 134 may respectively be formed of and include conductive material. In some embodiments, the first word line contact structures 132 and the second word line contact structures 134 are individually formed of and include one or more of W, Ru, Mo, and TiN_{y}.

Within the digit line exit regions 104, the memory array structure 100 further includes first additional digit line contact structures 136 and second additional digit line contact structures 138. Within an individual digit line exit region 104, the first additional digit line contact structures 136 may vertically extend between and couple some of the RDM structures 126 and some of the digit line structures 122; and the second additional digit line contact structures 138 may vertically extend between and couple some of the RDM structures 126 and some of the first routing structures 140 vertically overlying the memory cells 130. The first additional digit line contact structures 136 and second additional digit line contact structures 138 may be considered to be so-called “edge of array” digit line contact structures. An individual first additional digit line contact structure 136 may be formed to have an upper surface in physical contact with one of the RDM structures 126; and a lower surface on, within, or below one of the word line structures 116. As shown in FIG. 1B, in some embodiments, an individual first additional digit line contact structure 136 is formed to terminate below one of the digit line structures 122, such that a lower boundary of the first additional digit line contact structure 136 is positioned below a lower boundary of the digit line structure 122 (e.g., within vertical boundaries of one of the second isolation structures 114B). Outer sidewalls of the first additional digit line contact structure 136 may physically contact inner sidewalls of the digit line structure 122. In addition, an individual second additional digit line contact structures 138 may be formed to have an upper surface in physical contact with one of the conductive routing structures 14; and a lower surface on, within, or below one of the RDM structures 126. The first additional digit line contact structures 136 and second additional digit line contact structures 138 may respectively be formed of and include conductive material. In some embodiments, the first additional digit line contact structures 136 and second additional digit line contact structures 138 are individually formed of and include one or more of W, Ru, Mo, and TiN_{y}.

Still referring to FIG. 1B, at least one conductive routing tier (e.g., at least two conductive routing tiers) including the first routing structures 140 may be formed vertically over memory cells 130. One or more of the first routing structures 140 may be coupled to one or more other of the first routing structures 140 vertically offset therefrom by way of first contact structures 142. The first routing structures 140 and the first contact structures 142 may respectively be formed of and include conductive material. In some embodiments, the first routing structures 140 and the first contact structures 142 are individually formed of and include one or more of W, Ru, Mo, and TiN_{y}.

A first isolation material 144 may be formed on or over portions of at least the first base structure 108, the first dielectric material 120, the digit line capping structures 124, the RDM structures 126, the storage node devices 128, the memory cells 130, the first word line contact structures 132, the second word line contact structures 134, the first additional digit line contact structures 136, the second additional digit line contact structures 138, the first routing structures 140, and the first contact structures 142. The first isolation material 144 may be formed of and include at least one insulative material. In some embodiments, the first isolation material 144 is formed of and includes dielectric oxide material, such as SiOₓ (e.g., SiO₂). The first isolation material 144 may be substantially homogeneous, or the first isolation material 144 may be heterogeneous. An upper surface of the first isolation material 144 may be formed to be substantially planar. In some embodiments, the upper surface of the first isolation material 144 is formed to be substantially coplanar with upper surfaces of uppermost ones of the first routing structures 140. In additional embodiments, the upper surface of the first isolation material 144 is formed vertically overlie the upper surfaces of the uppermost ones of the first routing structures 140.

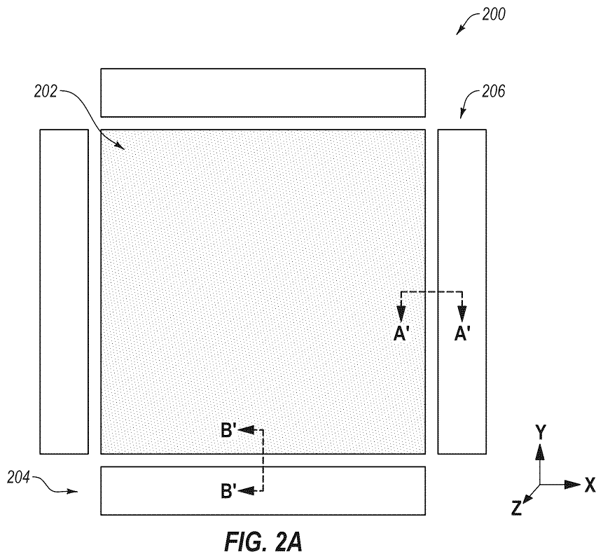

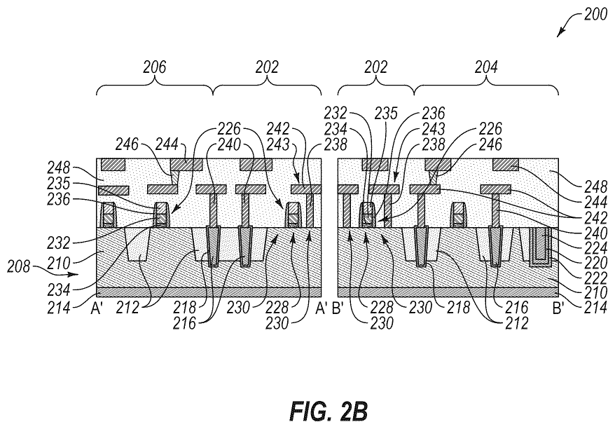

Referring next to FIG. 2A, illustrated is a simplified, partial plan view of a control circuitry structure 200 (e.g., a second wafer, a second die) at an early processing stage of the method of forming a microelectronic device (e.g., the memory device, such as the DRAM device), in accordance with embodiments of the disclosure. As shown in FIG. 2A, the control circuitry structure 200 may be formed to include a control circuitry region 202, first peripheral regions 204 horizontally neighboring the control circuitry region 202 in a Y-direction (e.g., a first horizontal direction), and second peripheral regions 206 horizontally neighboring the control circuitry region 202 in an X-direction (e.g., a second horizontal direction) orthogonal to the Y-direction. The control circuitry region 202, the first peripheral regions 204, and the second peripheral regions 206 are each described in further detail below. FIG. 2B is a diagram showing different simplified, vertical cross sectional views of the control circuitry structure 200 shown in FIG. 2A, taken about lines A′-A′ and B′-B′ of FIG. 2A. The vertical cross section of the control circuitry structure 200 taken about line A′-A′ is a view of an XZ-plane of a portion of the control circuitry structure 200 horizontally overlapping the control circuitry region 202 and one of the first peripheral regions 204 of the control circuitry structure 200. The vertical cross section of the control circuitry structure 200 taken about line B′-B′ is a view of a YZ-plane of an additional portion of the control circuitry structure 200 overlapping the control circuitry region 202 and one of the second peripheral regions 206 of the control circuitry structure 200.

Referring to FIG. 2A, the control circuitry region 202 of the control circuitry structure 200 includes control logic circuitry of the control circuitry structure 200 within a horizontal area thereof. The control logic circuitry of the control circuitry region 202 of the control circuitry structure 200 may be configured to be operatively associated with circuitry (e.g., memory cells) of the memory array structure 100 (FIGS. 1A and 1B), as described in further detail below. In some embodiments, the control circuitry region 202 is configured to at least partially (e.g., substantially) horizontally overlap a respective array region 102 (FIGS. 1A and 1B) of the memory array structure 100 (FIGS. 1A and 1B) following subsequent attachment of the control circuitry structure 200 to the memory array structure 100 (FIGS. 1A and 1B), as also described in further detail below. For clarity and ease of understanding of the drawings and related description, FIG. 2A depicts the control circuitry structure 200 as including one (1) control circuitry region 202, but the control circuitry structure 200 may be formed to include multiple (e.g., more than one (1)) control circuitry regions 202 horizontally offset (e.g., in one or more of the X-direction and the Y-direction) from one another. For example, the control circuitry structure 200 may include greater than or equal to four (4) control circuitry regions 202, greater than or equal to eight (8) control circuitry regions 202, greater than or equal to sixteen (16) control circuitry regions 202, greater than or equal to thirty-two (32) control circuitry regions 202, greater than or equal to sixty-four (64) control circuitry regions 202, greater than or equal to one hundred twenty eight (128) control circuitry regions 202, greater than or equal to two hundred fifty six (256) control circuitry regions 202, greater than or equal to five hundred twelve (512) control circuitry regions 202, or greater than or equal to one thousand twenty-four (1024) control circuitry regions 202. In some embodiments, a quantity of the control circuitry regions 202 of the control circuitry structure 200 substantially equals a quantity of the array regions 102 (FIGS. 1A and 1B) of the memory array structure 100 (FIGS. 1A and 1B).

The first peripheral regions 204 of the control circuitry structure 200 respectively include additional circuitry (e.g., peripheral circuitry) of the control circuitry structure 200 within a horizontal area thereof. In some embodiments, the first peripheral regions 204 are configured to at least partially (e.g., substantially) horizontally overlap respective digit line exit regions 104 (FIGS. 1A and 1B) of the memory array structure 100 (FIGS. 1A and 1B) following subsequent attachment of the control circuitry structure 200 to the memory array structure 100 (FIGS. 1A and 1B), as described in further detail below. In some embodiments, a quantity of the first peripheral regions 204 of the control circuitry structure 200 substantially equals a quantity of the digit line exit regions 104 (FIGS. 1A and 1B) of the memory array structure 100 (FIGS. 1A and 1B). As shown in FIG. 2A, the first peripheral regions 204 may respectively horizontally extend in the X-direction. An individual control circuitry region 202 of the control circuitry structure 200 may be horizontally interposed between horizontally neighboring first peripheral regions 204 of the control circuitry structure 200 in the Y-direction.

The second peripheral regions 206 of the control circuitry structure 200 respectively include further circuitry (e.g., further peripheral circuitry) of the control circuitry structure 200 within a horizontal area thereof. In some embodiments, the second peripheral regions 206 are configured to at least partially (e.g., substantially) horizontally overlap respective word line exit regions 106 (FIGS. 1A and 1B) of the memory array structure 100 (FIGS. 1A and 1B) following subsequent attachment of the control circuitry structure 200 to the memory array structure 100 (FIGS. 1A and 1B), as described in further detail below. In some embodiments, a quantity of the second peripheral regions 206 of the control circuitry structure 200 substantially equals a quantity of the word line exit regions 106 (FIGS. 1A and 1B) of the memory array structure 100 (FIGS. 1A and 1B). As shown in FIG. 2A, the second peripheral regions 206 may respectively horizontally extend in the Y-direction. An individual control circuitry region 202 of the control circuitry structure 200 may be horizontally interposed between horizontally neighboring second peripheral regions 206 of the control circuitry structure 200 in the X-direction.

Referring next to FIG. 2B, the control circuitry structure 200 may be formed to include a second base structure 208 including additional semiconductor material 210 and additional isolation structures 212 (e.g., additional STI structures) vertically extending into the additional semiconductor material 210.

The second base structure 208 comprises a base material or construction upon which additional features (e.g., materials, structures, devices) of the control circuitry structure 200 are formed. The second base structure 208 may comprise a semiconductor structure (e.g., a semiconductor wafer), or a base semiconductor material on a supporting structure. For example, the second base structure 208 may comprise a conventional silicon substrate (e.g., a conventional silicon wafer), or another bulk substrate comprising a semiconductor material. In some embodiments, the second base structure 208 comprises a silicon wafer. The second base structure 208 may include one or more layers, structures, and/or regions formed therein and/or thereon.

As shown in FIG. 2B, the control circuitry structure 200 may include a second isolation material 214 covering one or more surfaces (e.g., a lower surface) of the additional semiconductor material 210 of the second base structure 208. The second isolation material 214 may be formed of and include at least one insulative material. A material composition of the second isolation material 214 may be substantially the same as a material composition of the first isolation material 144 (FIG. 1B) of the memory array structure 100 (FIGS. 1A and 1B); or the material composition of the second isolation material 214 may be different than the material composition of the first isolation material 144 (FIG. 1B). In some embodiments, the second isolation material 214 is formed of and includes a dielectric oxide material, such as SiOₓ (e.g., SiO₂). The second isolation material 214 may be substantially homogeneous, or the second isolation material 214 may be heterogeneous.

The additional isolation structures 212 may comprise trenches (e.g., openings, vias, apertures) within the additional semiconductor material 210 of the second base structure 208 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the additional isolation structures 212 are respectively formed of and include SiOₓ (e.g., SiO₂).

The additional isolation structures 212 may, for example, be employed as STI structures within the second base structure 208. The additional isolation structures 212 may be formed to vertically extend partially (e.g., less than completely) through the second base structure 208. In some embodiments, a vertical depth (e.g., vertical height) of the additional isolation structures 212 is within a range of from about 200 nanometers (nm) to about 2000 nm. Each of the additional isolation structures 212 may be formed to exhibit substantially the same dimensions and shape as each other of the additional isolation structures 212, or at least one of the additional isolation structures 212 may be formed to exhibit one or more of different dimensions and a different shape than at least one other of the additional isolation structures 212. As a non-limiting example, each of the additional isolation structures 212 may be formed to exhibit substantially the same vertical dimension(s) and substantially the same vertical cross-sectional shape(s) as each other of the additional isolation structures 212; or at least one of the additional isolation structures 212 may be formed to exhibit one or more of different vertical dimension(s) and different vertical cross-sectional shape(s) than at least one other of the additional isolation structures 212. In some embodiments, the additional isolation structures 212 are all formed to vertically extend to and terminate at substantially the same depth within the additional semiconductor material 210 of the second base structure 208. In additional embodiments, at least one of the additional isolation structures 212 is formed to vertically extend to and terminate at a relatively deeper depth within the additional semiconductor material 210 of the second base structure 208 than at least one other of the additional isolation structures 212. As another non-limiting example, each of the additional isolation structures 212 may be formed to exhibit substantially the same horizontal dimension(s) and substantially the same horizontal cross-sectional shape(s) as each other of the additional isolation structures 212; or at least one of the additional isolation structures 212 may be formed to exhibit one or more of different horizontal dimension(s) (e.g., relatively larger horizontal dimension(s), relatively smaller horizontal dimension(s)) and different horizontal cross-sectional shape(s) than at least one other of the additional isolation structures 212. In some embodiments, at least one of the additional isolation structures 212 is formed to have one or more different horizontal dimensions (e.g., in the X-direction and/or in the Y-direction) than at least one other of the additional isolation structures 212.

With continued reference to FIG. 2B, the control circuitry structure 200 further includes anchor contact structures 216 (also referred to herein as “A-CON” structures) within horizontal areas of some of the additional isolation structures 212. The anchor contact structures 216 may be formed to vertically extend through the some of the additional isolation structures 212 and into portions of the additional semiconductor material 210 vertically underlying the some of the additional isolation structures 212. An individual anchor contact structure 216 may, for example, vertically extend from an upper surface of a respective additional isolation structure 212, completely through the additional isolation structure 212, and to vertical position within the additional semiconductor material 210 vertically underlying a lowermost boundary (e.g., a lowermost surface) of the additional isolation structure 212. The anchor contact structures 216 may vertically extend partially (e.g., less than completely) through portions of the additional semiconductor material 210 vertically underlying the additional isolation structures 212. In some embodiments, a vertical depth (e.g., vertical height) of an individual anchor contact structure 216 is within a range of from about 200 nm to about 2000 nm. The vertical depth (e.g., vertical height) of an individual anchor contact structure 216 is greater than the vertical depth (e.g., vertical height) of a respective additional isolation structure 212 that the anchor contact structure 216 horizontally overlaps and vertically extends through. The anchor contact structures 216 may be configured to promote desirable stress control within the second base structure 208 during subsequent processing acts (e.g., material removal acts, such as vertical thinning acts) of the method of forming of a microelectronic device of the disclosure. The anchor contact structures 216 may individually be formed of and include conductive material. In some embodiments, the anchor contact structures 216 are individually formed of and include metallic material, such one or more of W, Ru, Mo, and TiN_{y}.

A dielectric liner material 218 may be formed on or over surfaces (e.g., side surfaces, bottom surfaces) of the anchor contact structures 216. In some embodiments, the dielectric liner material 218 substantially continuously extends over and substantially covers portions of side surfaces and bottom surfaces of the anchor contact structures 216. The dielectric liner material 218 may be interposed between the anchor contact structures 216 and the additional semiconductor material 210 of the second base structure 208. The dielectric liner material 218 may have a thickness within a range of from about two (2) nm to about 10 nm, such as from about 2 nm to about 8 nm, or from about 2 nm to about 5 nm. The dielectric liner material 218 may be formed of and include insulative material. In some embodiments, the dielectric liner material 218 is formed of and includes dielectric oxide material (e.g., SiOₓ, such as SiO₂).

Still referring to FIG. 2B, the control circuitry structure 200 may further include power rail structures 220 (also referred to herein as “buried power rail structures”) vertically extending into the additional semiconductor material 210 of the second base structure 208. The power rail structures 220 may be horizontally positioned outside of horizontal areas of the control circuitry regions 202 of the control circuitry structure 200, such as within horizontal areas of one or more of the first peripheral regions 204 and the second peripheral regions 206 of the control circuitry structure 200. As a non-limiting example, as shown in FIG. 2B, an individual power rail structure 220 may be positioned within a horizontal area of one of the first peripheral regions 204 of the control circuitry structure 200. As another non-limiting example, an individual power rail structure 220 may be positioned within a horizontal area of one of the second peripheral regions 206 of the control circuitry structure 200. In some embodiments, the power rail structures 220 are formed to horizontally frame (e.g., substantially horizontally circumscribe) the control circuitry region(s) 202 of the control circuitry structure 200. The power rail structures 220 may individually be formed of and include conductive material.

As shown in FIG. 2B, in some embodiments, the power rail structures 220 are formed within horizontal areas of some other of the additional isolation structures 212 outside of the horizontal boundaries of the control circuitry region(s) 202. The additional isolation structures 212 may be formed to vertical extend through the some other of the additional isolation structures 212 and into portions of the additional semiconductor material 210 vertically underlying the some other of the additional isolation structures 212. An individual power rail structure 220 may, for example, vertically extend from an upper surface of a respective additional isolation structure 212, completely through the additional isolation structure 212, and to vertical position within the additional semiconductor material 210 vertically underlying a lowermost boundary (e.g., a lowermost surface) of the additional isolation structure 212. The power rail structures 220 may vertically extend partially (e.g., less than completely) through portions of the additional semiconductor material 210 vertically underlying the additional isolation structures 212. In some embodiments, a vertical depth (e.g., vertical height) of an individual power rail structure 220 is within a range of from about 200 nm to about 2000 nm. The vertical depth (e.g., vertical height) of an individual power rail structure 220 is greater than the vertical depth (e.g., vertical height) of a respective additional isolation structure 212 that the power rail structure 220 horizontally overlaps and vertically extends through.

In additional embodiments, one or more of the power rail structures 220 is formed outside of the horizontal boundaries of the control circuitry region(s) 202, and outside of horizontal areas the additional isolation structures 212. For example, an individual power rail structure 220 may be horizontally positioned within the first peripheral region 204 of the control circuitry structure 200, but may not be positioned within a horizontal area of one of the additional isolation structures 212 horizontally positioned within the first peripheral region 204. The power rail structure 220 may, for example, be embedded (e.g., buried) within the additional semiconductor material 210 of the second base structure 208, but not within the insulative material of one of the additional isolation structures 212 of the second base structure 208. However, the power rail structures 220 may still only partially (e.g., less than completely) vertically extend through the additional semiconductor material 210 of the second base structure 208. In some such embodiments, a vertical depth (e.g., vertical height) of an individual power rail structure 220 is within a range of from about 200 nm to about 2000 nm.

The power rail structures 220 may individually exhibit horizontally elongate shapes, as well as desired vertical cross-sectional shapes. As shown in FIG. 2B, in some embodiments, an individual power rail structure 220 is formed to exhibit a generally “U-shaped” vertical cross-sectional shape. For example, the power rail structure 220 may include two (2) side portions horizontally extending in parallel with one another in a first direction and horizontally offset from one another in a second direction orthogonal to the first direction, and a bottom portion integral with and continuously horizontally extending from and between lower sections of the two (2) side portions.

An additional dielectric liner material 222 may be formed on or over outer surfaces (e.g., outside side surfaces, lowermost surfaces) of the power rail structures 220. In some embodiments, the additional dielectric liner material 222 substantially continuously extends over and substantially covers portions of outside side surfaces and lowermost surfaces of the power rail structures 220. The additional dielectric liner material 222 may be interposed between the power rail structures 220 and the additional semiconductor material 210 of the second base structure 208. The additional dielectric liner material 222 may have a thickness within a range of from about two (2) nm to about 10 nm, such as from about 2 nm to about 8 nm, or from about 2 nm to about 5 nm. The additional dielectric liner material 222 may be formed of and include insulative material. In some embodiments, the additional dielectric liner material 222 is formed of and includes dielectric oxide material (e.g., SiOₓ, such as SiO₂).

A fill material 224 may be formed on or over inner surfaces (e.g., inner side surfaces, inner floor surfaces) of the power rail structures 220. The fill material 224 may, for example, substantially fill a space bordered by the inner surfaces of an individual power rail structure 220. The fill material 224 may, for example, be formed of and include one or more of sacrificial material and conductive material. If the fill material 224 is formed of and includes sacrificial material, the fill material 224 may be substantially removed and replaced with another material (e.g., conductive material) at a later processing stage of the method of forming a microelectronic device, as described in further detail below. For example, the fill material 224 may be selectively removable (e.g., selectively etchable) relative to the conductive material of the power rail structures 220. Employing the fill material 224 as a sacrificial material may, for example, promote desirable stress control within the second base structure 208 during subsequent processing acts (e.g., material removal acts, such vertical thinning acts) prior to the removal and replacement of the fill material 224. In some such embodiments, the fill material 224 is formed of and includes polycrystalline silicon. However, if the fill material 224 is formed of and includes conductive material, the fill material 224 may be at least partially (e.g., substantially) maintained (e.g., may not be substantially removed) at later processing stages of the method of forming a microelectronic device. In some such embodiments, the fill material 224 is formed of and includes metallic material, such one or more of W, Ru, Mo, and TiN_{y}.

Still referring to FIG. 2B, the control circuitry structure 200 may further include transistors 226. The transistors 226 may individually include conductively doped regions 230 (e.g., source/drain regions), a channel region 228, a gate structure 232 (e.g., a gate electrode), and a gate dielectric material 234. For an individual transistor 226, the conductively doped regions 230 thereof may be formed within the additional semiconductor material 210 of the second base structure 208; the channel region 228 thereof may be formed within the additional semiconductor material 210 of the second base structure 208 and may be horizontally interposed between the conductively doped regions 230 thereof; the gate structure 232 thereof may vertically overlie and horizontally overlap the channel region 228 thereof; and the gate dielectric material 234 (e.g., dielectric oxide material) may be vertically interposed (e.g., in the Z-direction (FIG. 2A)) between the gate structure 232 and the channel region 228.

For an individual transistor 226, the conductively doped regions 230 thereof may comprise additional semiconductor material 210 of the second base structure 208 doped with one or more desired conductivity-enhancing dopants. In some embodiments, the conductively doped regions 230 of the transistor 226 comprise the additional semiconductor material 210 doped with at least one N-type dopant (e.g., one or more of phosphorus, arsenic, antimony, and bismuth). In some of such embodiments, the channel region 228 of the transistor 226 comprises the additional semiconductor material 210 doped with at least one P-type dopant (e.g., one or more of boron, aluminum, and gallium). In some other of such embodiments, the channel region 228 of the transistor 226 comprises substantially undoped additional semiconductor material 210. In additional embodiments, for an individual transistor 226, the conductively doped regions 230 thereof comprise the additional semiconductor material 210 doped with at least one P-type dopant (e.g., one or more of boron, aluminum, and gallium). In some of such additional embodiments, the channel region 228 of the transistor 226 comprises the additional semiconductor material 210 doped with at least one N-type dopant (e.g., one or more of phosphorus, arsenic, antimony, and bismuth). In some other of such additional embodiments, the channel region 228 of the transistor 226 comprises substantially undoped additional semiconductor material 210.

The gate structures 232 (e.g., gate electrodes) may individually horizontally extend between and be employed by multiple transistors 226. The gate structures 232 may be formed of and include conductive material. The gate structures 232 may individually be substantially homogeneous, or the gate structures 232 may individually be heterogeneous. In some embodiments, the gate structures 232 are each substantially homogeneous. In additional embodiments, the gate structures 232 are each heterogeneous. Individual gate structures 232 may, for example, be formed of and include a stack of at least two different conductive materials.

Still referring to FIG. 2B, the control circuitry structure 200 further includes second contact structures 238 vertically overlying and in contact (e.g., physical contact, electrical contact) with the conductively doped regions 230 of the transistors 226; and third contact structures 240 vertically overlying and in contact (e.g., physical contact, electrical contact) with the anchor contact structures 216. In some embodiments, the second contact structures 238 vertically overlie, horizontally overlap, and physically contact the conductively doped regions 230 of the transistors 226; and the third contact structures 240 vertically overlie, horizontally overlap, and physically contact anchor contact structures 216. The second contact structures 238 and third contact structures 240 may individually be formed of and include conductive material. A material composition of the second contact structures 238 may be substantially the same as a material composition of the third contact structures 240, or the material composition of one or more of the second contact structures 238 may be different than the material composition of one or more of the third contact structures 240. In some embodiments, the second contact structures 238 and the third contact structures 240 are individually formed of and include one or more of W, Ru, Mo, and TiN_{y}.

The control circuitry structure 200 further includes second routing structures 242 vertically overlying the transistors 226. As shown in FIG. 2B, some of the second routing structures 242 may be coupled to the second contact structures 238 (and, hence, the transistors 226); and some other of the second routing structures 242 may be coupled to the third contact structures 240 (and, hence, the anchor contact structures 216). The second routing structures 242 may respectively be formed of and include conductive material. In some embodiments, the second routing structures 242 are individually formed of and include one or more of W, Ru, Mo, and TiN_{y}.

With continued collective reference to FIG. 2B, the transistors 226, the second contact structures 238, and at least some of the second routing structures 242 may form control logic circuitry of various control logic devices 243 configured to control various operations of various features (e.g., the memory cells 130 (FIG. 1B)) of a microelectronic device (e.g., a memory device, such as a DRAM device) to be formed through the methods of disclosure. In some embodiments, the control logic devices 243 comprise complementary metal-oxide-semiconductor (CMOS) circuitry. As a non-limiting example, the control logic devices 243 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions (e.g., the control circuitry region 202, the first peripheral regions 204, the second peripheral region 206) of the control circuitry structure 200 may have different control logic devices 243 formed within horizontal areas thereof.

Still referring to FIG. 2B, at least one additional conductive routing tier including the third routing structures 244 may be formed vertically over the second routing structures 242. One or more of the third routing structures 244 may be coupled to one or more other of the second routing structures 242 vertically thereunder by way of fourth contact structures 246. The third routing structures 244 and the fourth contact structures 246 may respectively be formed of and include conductive material. In some embodiments, the third routing structures 244 and the fourth contact structures 246 are individually formed of and include one or more of W, Ru, Mo, and TiN_{y}.

A third isolation material 248 may be formed on or over portions of at least the second base structure 208, the transistors 226, the second contact structures 238, the third contact structures 240, the second routing structures 242, control logic devices 243, the third routing structures 244, and the fourth contact structures 246. The third isolation material 248 may be formed of and include at least one insulative material. A material composition of the third isolation material 248 may be substantially the same as a material composition of the first isolation material 144 (FIG. 1B) of the memory array structure 100 (FIGS. 1A and 1B); or the material composition of the third isolation material 248 may be different than the material composition of the first isolation material 144 (FIG. 1B). In some embodiments, the third isolation material 248 is formed of and includes a dielectric oxide material, such as SiOₓ (e.g., SiO₂). The third isolation material 248 may be substantially homogeneous, or the third isolation material 248 may be heterogeneous. An upper surface of the third isolation material 248 may be formed to be substantially planar. In some embodiments, the upper surface of the third isolation material 248 is formed to be substantially coplanar with upper surfaces of uppermost ones of the third routing structures 244. In additional embodiments, the upper surface of the third isolation material 248 is formed vertically overlie the upper surfaces of the uppermost ones of the third routing structures 244.

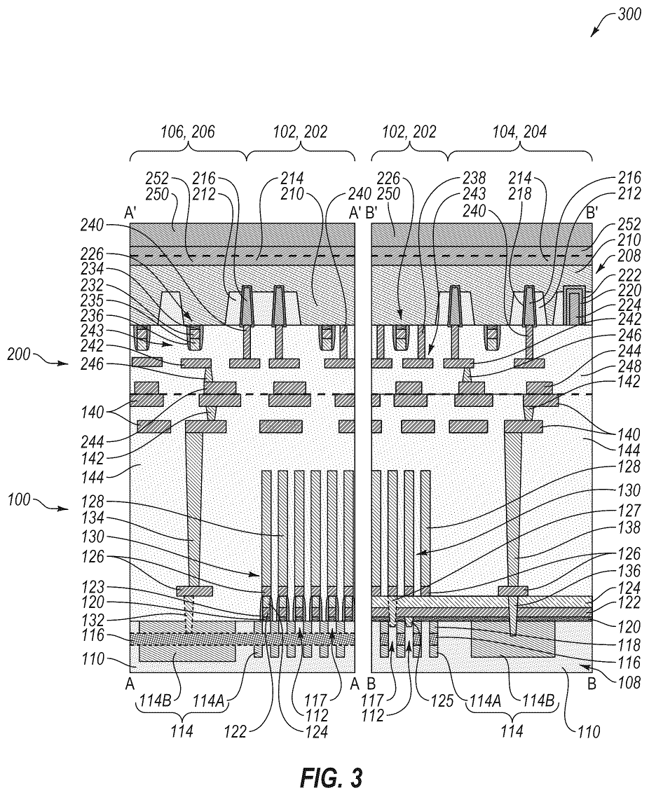

Referring next to FIG. 3, illustrated is a diagram showing different simplified, vertical cross sectional views of an assembly 300 formed from the memory array structure 100 of FIGS. 1A and 1B and the control circuitry structure 200 of FIGS. 2A and 2B at a processing stage of the method of forming a microelectronic device following the processing stage of FIGS. 1A and 1B and the processing stage of FIGS. 2A and 2B. A third base structure 250 may be attached to the control circuitry structure 200, and then the combination of the third base structure 250 and the control circuitry structure 200 may be vertically inverted and attached (e.g., bonded) to the memory array structure 100 to form the assembly 300. As shown in FIG. 3, within the assembly 300, the control circuitry region 202, the first peripheral regions 204, and the second peripheral regions 206 of the control circuitry structure 200 may vertically overlie (e.g., in the Z-direction shown in FIGS. 1A and 2A) and horizontally overlap (e.g., in the X-direction and the Y-direction shown in FIGS. 1A and 2A) the array region 102, the digit line exit regions 104, and the word line exit regions 106 of the memory array structure 100, respectively. The assembly 300 may be formed such that the vertical cross section of the control circuitry structure 200 taken about line A′-A′ of FIG. 2A vertically overlies and horizontally overlaps the vertical cross section of the memory array structure 100 taken about line A-A of FIG. 1A; and such that the vertical cross section of the control circuitry structure 200 taken about line B′-B′ of FIG. 2A vertically overlies and horizontally overlaps the vertical cross section of the memory array structure 100 taken about line B-B of FIG. 1A. The vertical cross section of the assembly 300 about the combination of line A-A of the memory array structure 100 and line A′-A′ of the control circuitry structure 200 is a view of an XZ-plane of a portion of the assembly 300 horizontally overlapping the array region 102 and one of the digit line exit regions 104 of the memory array structure 100 as well as the control circuitry region 202 and one of the first peripheral regions 204 of the control circuitry structure 200. In addition, the vertical cross section of the assembly 300 about the combination of line B-B of the memory array structure 100 and line B′-B′ of the control circuitry structure 200 is a view of a YZ-plane of an additional portion of the assembly 300 horizontally overlapping the array region 102 and one of the word line exit regions 106 of the memory array structure 100 as well as the control circuitry region 202 and one of the second peripheral regions 206 of the control circuitry structure 200.

The third base structure 250 comprises a base material or construction upon which additional features (e.g., materials, structures, devices) of the formed. In some embodiments, the third base structure 250 comprises a wafer. The third base structure 250 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the third base structure 250 may comprise a semiconductor wafer (e.g., a silicon wafer), a glass wafer, or a ceramic wafer. The third base structure 250 may include one or more layers, structures, and/or regions formed therein and/or thereon.

As shown in FIG. 3, a fourth isolation material 252 may cover one or more surfaces of the third base structure 250. The fourth isolation material 252 may be formed of and include at least one insulative material. A material composition of the fourth isolation material 252 may be substantially the same as a material composition of the second isolation material 214 of the control circuitry structure 200; or the material composition of the fourth isolation material 252 may be different than the material composition of the second isolation material 214. In some embodiments, the fourth isolation material 252 is formed of and includes a dielectric oxide material, such as SiOₓ (e.g., SiO₂). The fourth isolation material 252 may be substantially homogeneous, or the fourth isolation material 252 may be heterogeneous.

To attach the third base structure 250 to the control circuitry structure 200, the fourth isolation material 252 may be provided in physical contact with the second isolation material 214 of the control circuitry structure 200, and the fourth isolation material 252 and the second isolation material 214 may be exposed to annealing conditions to form bonds (e.g., oxide-to-oxide bonds) between the fourth isolation material 252 and the second isolation material 214. By way of non-limiting example, fourth isolation material 252 and the second isolation material 214 may be exposed to a temperature greater than or equal to about 400° C. (e.g., within a range of from about 400° C. to about 800° C., greater than about 800° C.) to form oxide-to-oxide bonds between the fourth isolation material 252 and the second isolation material 214. In some embodiments, the fourth isolation material 252 and the second isolation material 214 are exposed to at least one temperature greater than about 800° C. to form oxide-to-oxide bonds between the fourth isolation material 252 and the second isolation material 214.

After attaching the third base structure 250 to the control circuitry structure 200, attaching the combination of the third base structure 250 to the control circuitry structure 200 to the memory array structure 100 may include bonding (e.g., oxide-to-oxide bonding) the third isolation material 248 of the control circuitry structure 200 to the first isolation material 144 of the memory array structure 100. By way of non-limiting example, the third isolation material 248 and the first isolation material 144 may be exposed to an annealing temperature greater than or equal to about 400° C. (e.g., within a range of from about 400° C. to about 800° C., greater than about 800° C.) to form oxide-to-oxide bonds between the third isolation material 248 and the first isolation material 144. In some embodiments, the third isolation material 248 and the first isolation material 144 are exposed to at least one temperature greater than about 800° C. to form oxide-to-oxide bonds between the third isolation material 248 and the first isolation material 144. While the third isolation material 248 and the first isolation material 144 are distinguished from one another by way of the dashed line representing an initial interface before the bonding process in FIG. 3, the third isolation material 248 and the first isolation material 144 may be integral and continuous with one another following the bonding process. The third isolation material 248 of the control circuitry structure 200 may be attached to the first isolation material 144 of the memory array structure 100 without a bond line.

In embodiments wherein upper surfaces of the first isolation material 144 and uppermost ones of the first routing structures 140 of the memory array structure 100 are formed to be substantially coplanar with one another and wherein upper surfaces of the third isolation material 248 and uppermost ones (prior to vertical inversion) of the third routing structures 244 of the control circuitry structure 200 are formed to be substantially coplanar with one another, attaching the combination of the third base structure 250 to the control circuitry structure 200 to the memory array structure 100 may further include bonding (e.g., metal-to-metal bonding) at least some of the third routing structures 244 to at least some of the first routing structures 140. Bonding the at least some of the third routing structures 244 to the at least some of the first routing structures 140 may result from the same annealing process employed to bond the third isolation material 248 and the first isolation material 144. By way of non-limiting example, the third routing structures 244 and the first routing structures 140 may be exposed to an annealing temperature greater than or equal to about 400° C. (e.g., within a range of from about 400° C. to about 800° C., greater than about 800° C.) to form metal-to-metal bonds between at least some of the third routing structures 244 and at least some of the first routing structures 140. In some embodiments, the third routing structures 244 and the first routing structures 140 are exposed to at least one temperature greater than about 800° C. to form metal-to-metal bonds between the third routing structures 244 and the first routing structures 140. As shown in FIG. 3, bonding an individual third routing structure 244 to an individual first routing structure 140 may form an individual routing structure. While the third routing structures 244 and the first routing structures 140 of the connected routing structures are distinguished from one another by way of the dashed line representing an initial interface before the bonding process in FIG. 3, the third routing structures 244 and the first routing structures 140 of the connected routing structures may be integral and continuous with one another following the bonding process. For an individual connected routing structure, the third routing structure 244 thereof may be attached to the first routing structure 140 thereof without a bond line.

For the formation of the assembly 300, a front side of the control circuitry structure 200 may be considered to be a side (e.g., end surface) most proximate to the control logic devices 243 (e.g., most proximate to the third routing structures 244), and a back side of the control circuitry structure 200 may be considered to be an additional side (e.g., additional end surface) relatively more distal from the control logic devices 243 (e.g., most proximate to the second isolation material 214) than the front side. In addition, a front side of the memory array structure 100 may be considered to be a side (e.g., end surface) most proximate to the first routing structures 140, and a back side of the memory array structure 100 may be considered to be an additional side (e.g., additional end surface) most proximate to the first base structure 108. Accordingly, in the configuration shown in FIG. 3, the assembly 300 may be formed to have a so-called “front-to-front” (F2F) arrangement (also referred to herein as a “face-to-face” arrangement) of the control circuitry structure 200 relative to the memory array structure 100 following the processing stage described with reference to FIG. 3.

As shown in FIG. 3, following the formation of the assembly 300, the power rail structures 220 may be horizontally positioned outside of horizontal areas of the array region(s) 102 of the memory array structure 100 (as well as the control circuitry region(s) 202 of the control circuitry structure 200), such as within horizontal areas of one or more of the digit line exit region(s) 104 of the memory array structure 100 (as well as one or more of the first peripheral region(s) 204 of the control circuitry structure 200) and/or one or more of the word line exit region(s) 106 of the memory array structure 100 (as well as one or more of the second peripheral region(s) 206 of the control circuitry structure 200). As a non-limiting example, as shown in FIG. 3, an individual power rail structure 220 may be positioned within a horizontal area of one of the digit line exit regions 104 of the memory array structure 100 (as well as one of the first peripheral regions 204 of the control circuitry structure 200). As another non-limiting example, an individual power rail structure 220 may be positioned within a horizontal area of the word line exit regions 106 of the memory array structure 100 (as well as one of the second peripheral regions 206 of the control circuitry structure 200). In some embodiments, within the assembly 300, the power rail structures 220 horizontally frame (e.g., substantially horizontally circumscribe) the array region(s) 102 of the memory array structure 100 (as well as the control circuitry region(s) 202 of the control circuitry structure 200).

In addition, as also shown in FIG. 3, following the formation of the assembly 300, the anchor contact structures 216 may be horizontally positioned within horizontal areas of the array region(s) 102, the digit line exit regions 104, and the word line exit regions 106 of the memory array structure 100 (as well as the control circuitry region(s) 202, the first peripheral regions 204, and the second peripheral regions 206 of the control circuitry structure 200). As a non-limiting example, at least one of the anchor contact structures 216 may be horizontally positioned within a horizontal area of an array region 102 of the memory array structure 100 (as well as within a horizontal area of a control circuitry region 202 of the control circuitry structure 200); at least one other of the anchor contact structures 216 may be horizontally positioned within a horizontal area of one of the digit line exit regions 104 of the memory array structure 100 (as well as within a horizontal area of one of the first peripheral regions 204 of the control circuitry structure 200); and at least one additional one of the anchor contact structures 216 may be horizontally positioned within a horizontal area of one of the word line exit regions 106 of the memory array structure 100 (as well as within a horizontal area of one of the second peripheral regions 206 of the control circuitry structure 200).

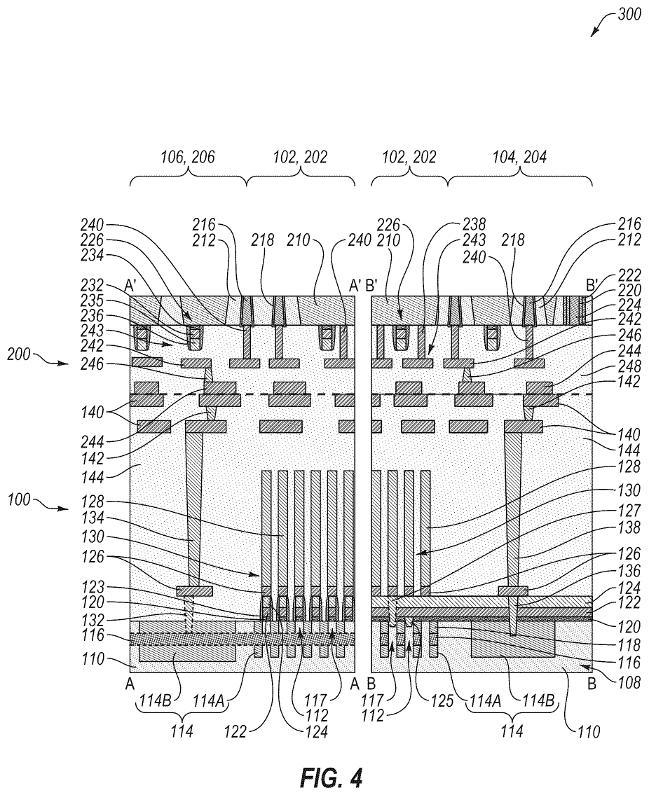

Referring next to FIG. 4, illustrated is a diagram showing the different simplified, vertical cross sectional views previously described with reference to FIG. 3, at a processing stage of the method of forming the microelectronic device following the processing stage previously described with reference to FIG. 3. As shown in FIG. 4, third base structure 250 (FIG. 3) and portions (e.g., upper portions following the vertical inversion of the control circuitry structure 200) of at least the additional semiconductor material 210, the dielectric liner material 218 (if any), the anchor contact structures 216, the additional dielectric liner material 222 (if any), and the power rail structures 220 may be removed. The material removal process also removes portions (e.g., upper portions following the vertical inversion of the control circuitry structure 200) of the fourth isolation material 252 (FIG. 3) and the second isolation material 214 (FIG. 3). Following the removal process, upper surfaces of remaining portions of the additional semiconductor material 210, the additional isolation structures 212, the anchor contact structures 216, the dielectric liner material 218 (if any), the power rail structures 220, the additional dielectric liner material 222 (if any), and the fill material 224 may be exposed (e.g., uncovered). The exposed upper surfaces of the remaining portions of the additional semiconductor material 210, the additional isolation structures 212, the anchor contact structures 216, the dielectric liner material 218 (if any), the power rail structures 220, the additional dielectric liner material 222 (if any), and the fill material 224 may be substantially coplanar with one another.

The third base structure 250 (FIG. 3) and the portions of at least the additional semiconductor material 210, the dielectric liner material 218, the anchor contact structures 216, the additional dielectric liner material 222, and the power rail structures 220 may be removed by detaching the third base structure 250 (FIG. 3) and then performing at least one thinning process (e.g., a CMP process; an etching process, such as a conventional dry etching process or a wet etching process) on the portions of the additional semiconductor material 210, the dielectric liner material 218 (if any), the anchor contact structures 216, the additional dielectric liner material 222 (if any), and the power rail structures 220. The remaining portions of the additional semiconductor material 210, the additional isolation structures 212, the anchor contact structures 216, the dielectric liner material 218 (if any), the power rail structures 220, the additional dielectric liner material 222 (if any), and the fill material 224 may be formed to exhibit a desired vertical height (e.g., in the Z-direction) through the material removal process, such as a vertical height less than or equal to about 1500 nm, such as within a range of from about 200 nm to about 1500 nm, from about 200 nm to about 1000 nm, from about 200 nm to about 500 nm, or about 200 nm. In this regard, the anchor contact structures 216 and the power rail structures 220 may control stresses during the thinning process (as well as the attachment processes previously described with reference to FIG. 3) to facilitate a relatively smaller vertical height of the additional semiconductor material 210 than may otherwise be facilitated through conventional methods.

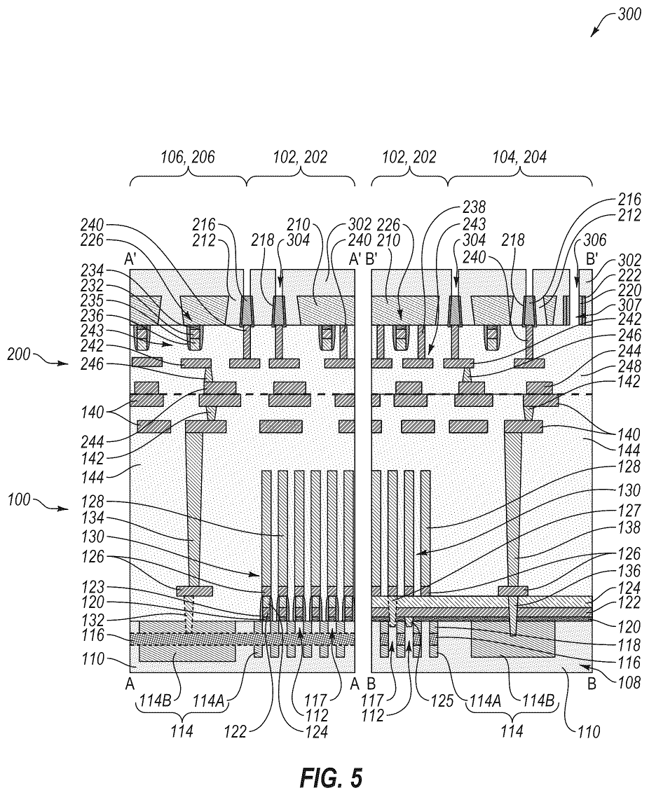

Referring next to FIG. 5, illustrated is a diagram showing the different simplified, vertical cross sectional views previously described with reference to FIG. 3, at a processing stage of the method of forming the microelectronic device following the processing stage previously described with reference to FIG. 4. As shown in FIG. 5, a fifth isolation material 302 may formed to cover upper surfaces of the remaining portions of the additional semiconductor material 210, the additional isolation structures 212, the anchor contact structures 216, the dielectric liner material 218, the power rail structures 220, the additional dielectric liner material 222, and the fill material 224. In addition, first vias 304 may be formed to vertically extend completely through the fifth isolation material 302 at horizontal positions of the remaining portions of the anchor contact structures 216; and second vias 306 may be formed to vertically extend completely through the fifth isolation material 302 at horizontal positions of the remaining portions the fill material 224 (FIG. 4) surrounded by the remaining portions of the power rail structures 220. The first vias 304 may at least partially expose the upper surfaces of remaining portions of the anchor contact structures 216, and the second vias 306 may at least partially expose the upper surfaces of remaining portions of the fill material 224 (FIG. 4). Furthermore, following the formation of the first vias 304 and the second vias 306, if the fill material 224 (FIG. 4) comprises sacrificial material, remaining portions of the fill material 224 (FIG. 4) may be removed (e.g., exhumed) through the second vias 306 to form openings 307 (e.g., void spaces, open volumes) in communication with the second vias 306 and exposing inner side surfaces of the remaining portions of the power rail structures 220.

The fifth isolation material 302 may be formed of and include at least one insulative material. A material composition of the fifth isolation material 302 may be substantially the same as a material composition of the additional isolation structures 212; or the material composition of the fifth isolation material 302 may be different than the material composition of the additional isolation structures 212. In some embodiments, the fifth isolation material 302 is formed of and includes a dielectric oxide material, such as SiOₓ (e.g., SiO₂). The fifth isolation material 302 may be substantially homogeneous, or the fifth isolation material 302 may be heterogeneous.

The first vias 304 may respectively be formed to at least partially horizontally overlap one of the anchor contact structures 216. In some embodiments, a horizonal center of an individual first via 304 is substantially aligned with a horizonal center of one of the anchor contact structures 216 vertically thereunder and partially exposed thereby. A horizontal area of a lower surface of an individual first via 304 may be less than, substantially equal to, or greater than a horizontal area of an upper surface of an individual anchor contact structure 216 vertically underlying and horizontally overlapping the first via 304.

The second vias 306 may respectively be formed to at least partially horizontally overlap the fill material 224 (FIG. 3) surrounded by remaining portions of the power rail structures 220. In some embodiments, for an individual second via 306, a horizonal center thereof is substantially aligned with a horizonal centerline of the fill material 224 (FIG. 3) exposed by the second via 306. A horizontal area of a lower surface of an individual second via 306 may be less than horizontal dimensions of an upper surface of the fill material 224 (FIG. 3) vertically underlying and partially exposed by the second via 306.

If the fill material 224 (FIG. 3) is formed of and includes sacrificial material, following the formation of the second vias 306, the fill material 224 (FIG. 3) may be selectively removed (e.g., selectively etched and exhumed) through the second vias 306 to form the openings 307. The openings 307 may have geometric configurations (e.g., shapes, dimensions) and positions corresponding to (e.g., substantially the same as) the geometric configurations and positions of the fill material 224 (FIG. 3) surrounded by remaining portions of the power rail structures 220. In some embodiments, the openings 307 elongate horizontal shapes that respectively follow horizontal paths of the remaining portions of the power rail structures 220 horizontally adjacent thereto. The openings 307 may substantially expose inner side surfaces of the remaining portions of the power rail structures 220 horizontally adjacent thereto. Lower boundaries of the openings 307 may be at least partially defined by portions of the third isolation material 248 exposed by the openings 307. Conversely, if the fill material 224 (FIG. 3) is formed of and includes conductive material, following the formation of the second vias 306, the fill material 224 (FIG. 3) may be at least partially maintained (e.g., may not be selectively etched and exhumed by way of the second vias 306). In such embodiments, the second vias 306 by vertically extend to and partially expose the fill material 224. Upper surfaces of remaining portions of the fill material 224 may at least partially define lower boundaries of the second vias 306.

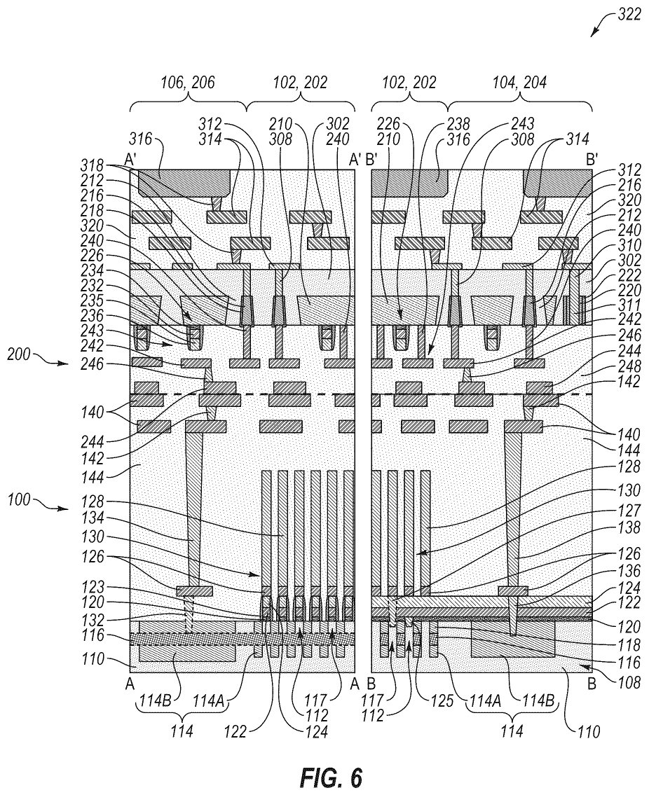

Referring next to FIG. 6, illustrated is a diagram showing the different simplified, vertical cross sectional views previously described with reference to FIG. 3, at a processing stage of the method of forming the microelectronic device following the processing stage previously described with reference to FIG. 5. As shown in FIG. 6, fifth contact structures 308 may be formed in the first vias 304 (FIG. 5); sixth contact structures 310 may be formed in the second vias 306 (FIG. 5); and if the openings 307 (FIG. 5) were formed, conductive fill structures 311 may be formed within the openings 307 (FIG. 5). Fourth routing structures 312 may then be formed vertically over and in contact with the fifth contact structures 308 and the sixth contact structures 310. Thereafter, back-end-of-line (BEOL) structures may be formed vertically over the fourth routing structures 312, as described in further detail below.

The fifth contact structures 308 may substantially fill the first vias 304 (FIG. 5). The fifth contact structures 308 may have geometric configurations (e.g., shapes, dimensions) and positions corresponding to (e.g., substantially the same as) the geometric configurations and positions of the first vias 304 (FIG. 5). As shown in FIG. 6, individual fifth contact structures 308 may contact (e.g., physically contact, electrically contact) individual anchor contact structures 216. The fifth contact structures 308 may respectively be formed of and include conductive material. In some embodiments, the fifth contact structures 308 are individually formed of and include one or more of W, Ru, Mo, and TiN_{y}.

The sixth contact structures 310 may substantially fill the second vias 306 (FIG. 5). The sixth contact structures 310 may have geometric configurations (e.g., shapes, dimensions) and positions corresponding to (e.g., substantially the same as) the geometric configurations and positions of the second vias 306 (FIG. 5). As shown in FIG. 6, if the conductive fill structures 311 are formed, individual sixth contact structures 310 may contact (e.g., physically contact, electrically contact) individual conductive fill structures 311. Conversely, if the openings 307 (FIG. 5) were not formed at the processing stage previously described herein with reference to FIG. 5, individual sixth contact structures 310 may contact (e.g., physically contact, electrically contact) the fill material 224 (FIG. 4) surrounded by remaining portions of the power rail structures 220. The sixth contact structures 310 may respectively be formed of and include conductive material. A material composition of the sixth contact structures 310 may be substantially the same as a material composition of the fifth contact structures 308; or the material composition of the sixth contact structures 310 may be different than the material composition of the fifth contact structures 308. In some embodiments, the sixth contact structures 310 are individually formed of and include one or more of W, Ru, Mo, and TiN_{y}.

If formed, the conductive fill structures 311 may substantially fill the openings 307 (FIG. 5). The conductive fill structures 311 may have geometric configurations (e.g., shapes, dimensions) and positions corresponding to (e.g., substantially the same as) the geometric configurations and positions of the openings 307 (FIG. 5). The conductive fill structures 311 may horizontally neighbor contact (e.g., physically contact, electrically contact) the inner side surfaces of the remaining portions of the power rail structures 220, and may vertically underlie and contact (e.g., physically contact, electrically contact) the sixth contact structures 310. In some embodiments, the conductive fill structures 311 are integral and continuous with the sixth contact structures 310 in contact therewith. The conductive fill structures 311 may respectively be formed of and include conductive material. A material composition of the conductive fill structures 311 may be substantially the same as a material composition of the sixth contact structures 310; or the material composition of the conductive fill structures 311 may be different than the material composition of the sixth contact structures 310. In some embodiments, the conductive fill structures 311 are individually formed of and include one or more of W, Ru, Mo, and TiN_{y}.

Still referring to FIG. 6, the fourth routing structures 312 may be formed to vertically overlie the fifth contact structures 308 and the sixth contact structures 310. For example, the fourth routing structures 312 may be formed on and may horizontally extend in desirable paths across upper surfaces of the fifth isolation material 302, the fifth contact structures 308, and the sixth contact structures 310. As shown in FIG. 6, some of the fourth routing structures 312 may be coupled to the fifth contact structures 308 (and, hence, the anchor contact structures 216 and at least some of the control logic devices 243); and some other of the fourth routing structures 312 may be coupled to the sixth contact structures 310 (and, hence, the power rail structures 220). The fourth routing structures 312 may respectively be formed of and include conductive material. In some embodiments, the fourth routing structures 312 are individually formed of and include one or more of W, Ru, Mo, and TiN_{y}.

As previously mentioned, BEOL structures may be formed vertically over the fourth routing structures 312. For example, at least one additional routing tier (e.g., at least two additional routing tiers) including fifth routing structures 314 may be formed over the fourth routing structures 312; and pad structures 316 may be formed over the fifth routing structures 314. In addition, seventh contact structures 318 may be formed to couple different fourth routing structures 312 with one another, different fourth routing structures 312, and different pad structures 316, as desired. Some of the fifth routing structures 314 may be coupled to some of the fourth routing structures 312 by way of some of the seventh contact structures 318; some of the fifth routing structures 314 may be coupled to some other of the fifth routing structures 314 by way of some other of the seventh contact structures 318; and some of the fifth routing structures 314 may be coupled to some of the pad structures 316 by way of yet still other of the seventh contact structures 318. The fourth routing structures 312, the fifth routing structures 314, the pad structures 316, and the seventh contact structures 318 may be configured such that the power rail structures 220 are coupled to power delivery networks and metallization (e.g., routing, contact, pad) pathways vertically thereover while being isolated from other metallization (e.g., other routing, other contact) pathways vertically thereunder. The fifth routing structures 314, the pad structures 316, and the seventh contact structures 318 may respectively be formed of and include conductive material. In some embodiments, the fifth routing structures 314, the pad structures 316, and the seventh contact structures 318 are individually formed of and include one or more of W, Cu, Al, Ru, Mo, and TiN_{y}.

Still referring to FIG. 6, a sixth isolation material 320 may be formed on or over portions of at least the fifth isolation material 302, the fourth routing structures 312, the fifth routing structures 314, the pad structures 316, and the seventh contact structures 318. The sixth isolation material 320 may be formed of and include at least one insulative material. A material composition of the sixth isolation material 320 may be substantially the same as a material composition of the fifth isolation material 302; or the material composition of the sixth isolation material 320 may be different than the material composition of the fifth isolation material 302. In some embodiments, the sixth isolation material 320 is formed of and includes a dielectric oxide material, such as SiOₓ (e.g., SiO₂). The sixth isolation material 320 may be substantially homogeneous, or the sixth isolation material 320 may be heterogeneous. In some embodiments, an upper surface of the sixth isolation material 320 is formed to be substantially coplanar with upper surfaces of the pad structures 316. In additional embodiments, the upper surface of the sixth isolation material 320 is formed to vertically overlie the upper surfaces of the pad structures 316. In such embodiments, openings may be formed within the sixth isolation material 320 to at least partially expose (and, hence, facilitate access to) the upper surfaces of the pad structures 316.

As shown in FIG. 6, the method described above with reference to FIGS. 1A through 6 may effectuate the formation of a microelectronic device 322 (e.g., a memory device, such as a DRAM device) including the features (e.g., structures, materials, devices) previously described herein. The microelectronic device 322 may include the memory array structure 100, the control circuitry structure 200 vertically overlying and bonded to the memory array structure 100 in a F2F arrangement of the control circuitry structure 200 and the memory array structure 100, and the fourth routing structures 312 and the BEOL structures (e.g., the fifth routing structures 314, the pad structures 316, the seventh contact structures 318) vertically overlying the control circuitry structure 200. At least some of the third routing structures 244, at least some of the fourth contact structures 246, at least some of the first routing structures 140, and at least some of the first contact structures 142 may be employed as local routing and interconnect structures for the microelectronic device 322 to, for example, couple the control logic devices 243 to the memory cells 130 vertically thereunder. In addition, at least some of the pad structures 316, at least some of the fifth routing structures 314, and at least some of the seventh contact structures 318 employed as global routing and interconnect structures for the microelectronic device 322 to, for example, receive global signals from an external bus, and to relay the global signals to other components (e.g., structures, devices) of the microelectronic device 322.

The configuration of the microelectronic device 322 may facilitate enhanced device performance (e.g., speed, data transfer rates, power consumption) relative to conventional microelectronic device configurations. For example, the configurations and positions (e.g., within the control circuitry structure 200) of the power rail structures 220 may mitigate power dissipation, reduce dynamic and static IR drop, improve signal integrity, and increase array efficiency as compared to conventional device configurations. In addition, the configurations and positions of the anchor contact structures 216 and the power rail structures 220 facilitate access to a power delivery network (e.g., by way of at least some of the fifth routing structures 314 and seventh contact structures 318), the pad structures 316, and additional BEOL structures from a backside of the control circuitry structure 200, and control stresses while attaching (e.g., bonding) the control circuitry structure 200 to the memory array structure 100 as well as during material thinning processes subsequently performed on the control circuitry structure 200 (e.g., facilitating relatively reduced vertical dimensions of the additional semiconductor material 210). Furthermore, the F2F attachment (e.g., bonding) of the control circuitry structure 200 to the memory array structure 100 may provide enhanced alignment margin as compared to conventional methods. Moreover, the method described above with reference to FIGS. 1A through 6 may resolve limitations on array (e.g., memory cell array) configurations, control logic device configurations, and associated device performance that may otherwise result from thermal budget constraints imposed by the formation and/or processing of arrays (e.g., memory cell arrays) of a microelectronic device.

Thus, in accordance with embodiments of the disclosure, a microelectronic device includes a memory array structure and a control circuitry structure vertically overlying and attached to the memory array structure. The memory array structure includes an array region having memory cells within a horizontal area thereof. The control circuitry structure includes a control circuitry region and a power rail structure. The control circuitry region horizontally overlaps the array region of the memory array structure and has control logic devices within a horizontal area thereof. At least some of the control logic devices are coupled to the memory cells of the memory array structure. The power rail structure is outside of the horizontal area of the control circuitry region.

Furthermore, in accordance with embodiments of the disclosure, a method of forming a microelectronic device includes forming a memory array structure including an array region having memory cells within a horizontal area thereof, the memory cells respectively comprising an access device and a capacitor vertically overlying and coupled to the access device. A control circuitry structure is formed and comprises control logic devices, anchor contact structures vertically overlying and coupled to the control logic devices, and power rail structures vertically overlapping the anchor contact structures. The control circuitry structure is attached to the memory array structure such that at least some of the control logic devices of the control circuitry structure are within the horizontal area of the array region of the memory array structure and such that the power rail structures are completely outside of the horizontal area of the array region of the memory array structure. Routing structures are formed vertically over the anchor contact structures and the power rail structures of the control circuitry structure, some of the routing structures are coupled to the anchor contact structures and some other of the routing structures are coupled to the power rail structures.

Moreover, in accordance with embodiments of the disclosure, a memory device includes a memory array structure and a control circuitry structure vertically overlying and bonded to the memory array structure. The memory array structure includes an array region having dynamic random access memory (DRAM) cells therein. The DRAM cells respectively include an access device and a capacitor vertically overlying and coupled to the access device. The control circuitry structure includes control logic devices, anchor contact structures, and a power rail structure. The control logic devices are within a control circuitry region horizontally overlapping the array region of the memory array structure. The anchor contact structures vertically extend through semiconductor material at least partially vertically overlying the control logic devices. The anchor contact structures are coupled to at least some of the control logic devices. The power rail structure vertically extends through the semiconductor material. The power rail structure is outside of horizontal areas of the control circuitry region of the control circuitry structure and the array region of the memory array structure.

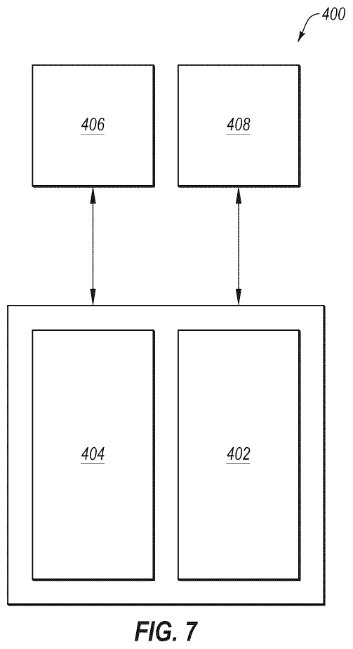

Microelectronic devices (e.g., the microelectronic device 322 (FIG. 6)) in accordance with embodiments of the disclosure may be used in embodiments of electronic systems of the disclosure. For example, FIG. 7 is a block diagram illustrating an electronic system 400 according to embodiments of disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 400 includes at least one memory device 402. The memory device 402 may comprise, for example, a microelectronic device (e.g., the microelectronic device 322 (FIG. 6)) previously described herein. The electronic system 400 may further include at least one electronic signal processor device 404 (often referred to as a “microprocessor”). The electronic signal processor device 404 may, optionally, comprise a microelectronic device (e.g., the microelectronic device 322 (FIG. 6)) previously described herein. While the memory device 402 and the electronic signal processor device 404 are depicted as two (2) separate devices in FIG. 7, in additional embodiments, a single (e.g., only one) memory/processor device having the functionalities of the memory device 402 and the electronic signal processor device 404 is included in the electronic system 400. In such embodiments, the memory/processor device may include a microelectronic device (e.g., the microelectronic device 322 (FIG. 6)) previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 comprise a single touchscreen device that can be used both to input information to the electronic system 400 and to output visual information to a user. The input device 406 and the output device 408 may communicate electrically with one or more of the memory device 402 and the electronic signal processor device 404.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a memory array structure comprises an array region having memory cells within a horizontal area thereof; and
a control circuitry structure vertically overlying and attached to the memory array structure, the control circuitry structure comprising:
a control circuitry region horizontally overlapping the array region of the memory array structure and having control logic devices within a horizontal area thereof, at least some of the control logic devices coupled to the memory cells of the memory array structure; and
a power rail structure outside of the horizontal area of the control circuitry region.

2. The microelectronic device of claim 1, wherein the control circuitry structure further comprises:
semiconductor material, transistors of the control logic devices partially positioned within the semiconductor material;
isolation structures vertically extending completely through the semiconductor material; and
anchor contact structures within horizontal areas of and vertically extending completely through at least some of the isolation structures, at least some of the anchor contact structures coupled to at least some of the control logic devices.

3. The microelectronic device of claim 2, wherein the anchor contact structures vertically overlap the power rail structure.

4. The microelectronic device of claim 2, wherein the power rail structure is substantially confined within vertical boundaries of the semiconductor material.

5. The microelectronic device of claim 4, wherein the power rail structure is within a horizontal area of and vertically extends completely through one of the isolation structures.

6. The microelectronic device of claim 1, wherein the control logic devices of the control circuitry structure are vertically positioned closer to the memory cells of the memory array structure than is the power rail structure of the control circuitry structure.

7. The microelectronic device of claim 1, wherein the control circuitry structure is attached to the memory array structure through a combination of oxide-to-oxide bonds and metal-to-metal bonds.

8. The microelectronic device of claim 1, further comprising:
routing structures vertically interposed between and coupled to the memory cells of the memory array structure and the control logic devices of the control circuitry structure; and
additional routing structures vertically overlying the control circuitry structure, some of the additional routing structures coupled to the control logic devices of the control circuitry structure, and some other of the additional routing structures coupled to the power rail structure of the control circuitry structure.

9. The microelectronic device of claim 1, wherein the memory cells of the memory array structure comprise dynamic random access memory (DRAM) cells, capacitors of the DRAM cells vertically positioned closer to the control logic devices of the control circuitry structure than are access devices of the DRAM cells.

10. A method of forming a microelectronic device, comprising:
forming a memory array structure including an array region having memory cells within a horizontal area thereof, the memory cells respectively comprising an access device and a capacitor vertically overlying and coupled to the access device;
forming a control circuitry structure comprising control logic devices, anchor contact structures vertically overlying and coupled to the control logic devices, and power rail structures vertically overlapping the anchor contact structures;
attaching the control circuitry structure to the memory array structure such that at least some of the control logic devices of the control circuitry structure are within the horizontal area of the array region of the memory array structure and such that the power rail structures are completely outside of the horizontal area of the array region of the memory array structure; and
forming routing structures vertically over the anchor contact structures and the power rail structures of the control circuitry structure, some of the routing structures coupled to the anchor contact structures and some other of the routing structures coupled to the power rail structures.

11. The method of claim 10, wherein forming the control circuitry structure comprises:
forming the anchor contact structures within horizontal areas of isolation structures partially vertically extending through a semiconductor material, the anchor contact structures vertically extending completely through the isolation structures and into the semiconductor material; and
forming the power rail structures to vertically extend partially through the semiconductor material, lower boundaries of the power rail structures vertically below lower boundaries of the isolation structures.

12. The method of claim 11, further comprising forming at least one of the power rail structures within a horizontal area of at least one of the isolation structures, the at least one of the power rail structures vertically extending completely through the at least one of the isolation structures and into the semiconductor material.

13. The method of claim 11, wherein attaching the control circuitry structure to the memory array structure comprises:
vertically inverting the control circuitry structure; and
bonding the control circuitry structure to the memory array structure through a combination of oxide-to-oxide bonding and metal-to-oxide bonding after vertically inverting the control circuitry structure.

14. The method of claim 13, further comprising, after bonding the control circuitry structure to the memory array structure:
removing upper portions of the semiconductor material, the anchor contact structures, and the power rail structures;
forming insulative material vertically over remaining portions of the portions of the semiconductor material, the anchor contact structures, and the power rail structures; and
forming conductive contacts vertically extending through the insulative material, some of the conductive contacts coupled to the anchor contact structures and some other of the conductive contacts coupled to the power rail structures.

15. The method of claim 14, forming conductive contacts vertically extending through the insulative material comprises:
forming first vias vertically extending through the insulative material and horizontally overlapping the anchor contact structures;
forming second vias vertically extending through the insulative material and respectively horizontally neighboring at least one of the power rail structures; and
filling the first vias and the second vias with conductive material to form the conductive contacts, the some of the conductive contacts formed within the first vias, and the some other of the conductive contacts formed within the second vias.

16. The method of claim 15, further comprising:
before filling the first vias and the second vias with the conductive material, selectively removing fill material horizontally neighboring the power rail structures through the second vias to form openings horizontally neighboring and partially exposing the power rail structures; and
substantially filling the openings with the conductive material while filling the first vias and the second vias with the conductive material.

17. The method of claim 10, wherein attaching the control circuitry structure to the memory array structure further comprises attaching the control circuitry structure to the memory array structure such that the control logic devices of the control circuitry structure are relatively vertically closer to the memory cells of the memory array structure than are the anchor contact structures and the power rail structures of the control circuitry structure.

18. A memory device, comprising:
a memory array structure including an array region having dynamic random access memory (DRAM) cells therein, the DRAM cells respectively comprising an access device and a capacitor vertically overlying and coupled to the access device; and
a control circuitry structure vertically overlying and bonded to the memory array structure, the control circuitry structure comprising:
control logic devices within a control circuitry region horizontally overlapping the array region of the memory array structure;
anchor contact structures vertically extending through semiconductor material at least partially vertically overlying the control logic devices, the anchor contact structures coupled to at least some of the control logic devices; and
a power rail structure vertically extending through the semiconductor material, the power rail structure outside of horizontal areas of the control circuitry region of the control circuitry structure and the array region of the memory array structure.

19. The memory device of claim 18, wherein the anchor contact structures and the power rail structure are within horizontal areas of and vertically extend through isolation structures vertically extending completely through the semiconductor material.

20. The memory device of claim 18, further comprising routing structures vertically overlying and coupled to the anchor contact structures and the power rail structure.
